(19) United States
(12) Patent Application Publication
(10) Pub. No.: US 2004/0158781 A1
(43) Pub. Date: Aug. 12, 2004

(54) Method for determining line faults in a bus system and bus system

(76) Inventor: Eric Pihet, Munchen (DE)

Correspondence Address: LERNER AND GREENBERG, P.A., POST OFFICE BOX 2480, HOLLYWOOD, FL, 33022-2480, US

(21) Appl. No.: 10/694,592

(22) Filed: Oct. 27, 2003

(30) Foreign Application Priority Data
Oct. 25, 2002 (DE) 102 49 856.3

(51) Int. Cl. G01R 31/28

(52) U.S. Cl. 714/712

(57) ABSTRACT

The invention relates to a method for checking for line faults in a bus system (1) which has at least two bus subscribers (2-5) which are connected for the purpose of data communication with one another to a data bus (6) which has at least two bus lines (7, 8), with the bus subscribers (2-5) being able to assume a recessive state and a dominant state, and with an internal high potential (VCC, VCC2) and an internal low potential (GND, GND2) being available in the bus subscribers,

with the check for a line fault being carried out by the bus subscriber (2) which is in the dominant state, and

with the check for line faults being carried out by comparison of voltage levels (VCANH, VCANL) on the bus lines (7, 8) with threshold values (Vref1, Vref3) which are related to the internal high level (VCC2) or to the internal low level (GND2) of the bus subscriber (2).

The invention also relates to a bus system in which at least one bus subscriber has a device for fault identification in order to carry out one of the methods mentioned above.

The invention relates to a method for checking for line faults in a bus system, and to a bus system.

Networked systems for control purposes, which are based on a wire-connected data bus as the communication medium, are becoming increasingly important. A network system such as this may, for example, be in the form of a local computer network. In the field of motor vehicle technology, it is known for two or more controllers to be networked in order to allow data interchange or data communication between the individual controllers. The complexity and material for the wiring can be saved to a considerable extent by creating a data protocol, which is sent between the controllers via one or more lines and in which the appropriate data can be entered at the locations that are provided for this purpose, and can be read out again, as well. Without a data bus such as this, a separate line would be required for each information item to be interchanged between the respective controllers.

One example of a network system such as this in motor vehicle electronics is the bus system in accordance with the CAN standard (Controller Area Network) . A CAN bus system is described, for example, in DE 195 230 31 A1 and in DE 35 06 118.

In networked systems such as these, a large number of electronic controllers—referred to as bus subscribers in the following text—communicate with one another via a bus network which, in the case of a CAN bus system, comprises two data lines of a data bus, which are twisted with one another and are typically sampled dominantly in antiphase. One bus subscriber has at least one transceiver for transmitting and/or receiving data, as well as a control unit, for example a microcontroller, for controlling the data transmission.

Data is written to the data bus by applying a specific voltage level to the data line or to the data lines for a specific time period. In order to allow interference-free communication between individual bus subscribers, it is necessary in this case for the controllers for the bus system to have a virtually identical reference ground potential. In the case of a motor vehicle, this is the vehicle ground to which all the electrical appliances in a motor vehicle are connected, as an equipotential surface.

Fault Identification, Fault Qualification

However, the probability of a fault in a bus system is not zero. Faults can occur, for example, in the event of a short circuit or a line discontinuity (no load) on the data lines, thus interfering with or interrupting the data transmission. Fault identification is therefore necessary.

However, one problem is that the fault symptoms of a short circuit of a no load can in some cases not be distinguished from one another. Furthermore, every fault does not necessarily lead to an interruption or a disturbance in the data transmission, either. In the case of some fault types, the operation of the bus system will even continue. For example, in the case of a high-speed CAN bus (HS-CAN), the bus will no longer operate in the event of a line discontinuity. In the case of a low-speed CAN bus (LS-CAN), this bus is still operable despite a line interruption, although the bus will no longer be free of ground shift. In the case of a line interruption in a two-wire or multiple-wire bus, it is advantageous to know which of the wires may be defective, in order in this way to simplify the repair.

In a CAN communications system, which comprises differential data lines CANL and CANH, the following fault states may occur:

1. Interrupted CANH line (no load);

2. Interrupted CANL line (no load);

3. Short circuit of the CANH line to a supply voltage, in a vehicle, by way of example, the battery voltage;

4. Short circuit of the CANL line to the reference ground potential GND;

5. Short circuit of the CANH line to the reference ground potential GND;

6. Short circuit of the CANL line to the supply voltage;

7. Short circuit of the CANH line to the CANL line.

It is therefore absolutely essential to identify and to qualify the nature of the fault state in order to make it possible to take actions in good time to maintain the data communication between the bus subscribers.

Modern bus systems are therefore equipped with devices for fault identification and fault determination, by means of which a fault in the bus lines can be identified, and the nature of the fault can be determined.

German Laid-Open Specification DE 195 23 031 A1 describes a data transmission system that uses a differential bus which has a fault identification device such as this. Some of the bus faults mentioned above are identified by a transceiver, by comparing the respective level of the corresponding bus line with an internal, defined threshold level. For example, a fault on the CANH line is identified by comparing the CANH level with an internal comparator threshold. If this level is higher than the predetermined comparator threshold, then this is identified after a specific time as a fault. This comparison is carried out irrespectively of whether the bus is in the dominant state or is in the recessive state.

Reference Ground Potential Shift (Ground Shift)

Ideally—as already mentioned above—each bus subscriber has a ground contact in order to ensure that all the bus subscribers are at a common reference ground potential. However, this is not always satisfied in reality. In fact, in the event of deterioration in the ground contact for individual bus subscribers, it is possible for a shift to occur in the reference ground potential GND relative to the other bus subscribers. A shift in the reference ground potential GND such as this is also referred to in the following text as a ground shift or GND shift. The reason for this is that other components in addition to the microcontroller and the transceiver may also be located on a bus subscriber and, in some circumstances, these can lead to a greater or lesser offset in the reference ground potential. The various bus subscribers in a networked bus system therefore frequently operate with respect to different reference potentials.

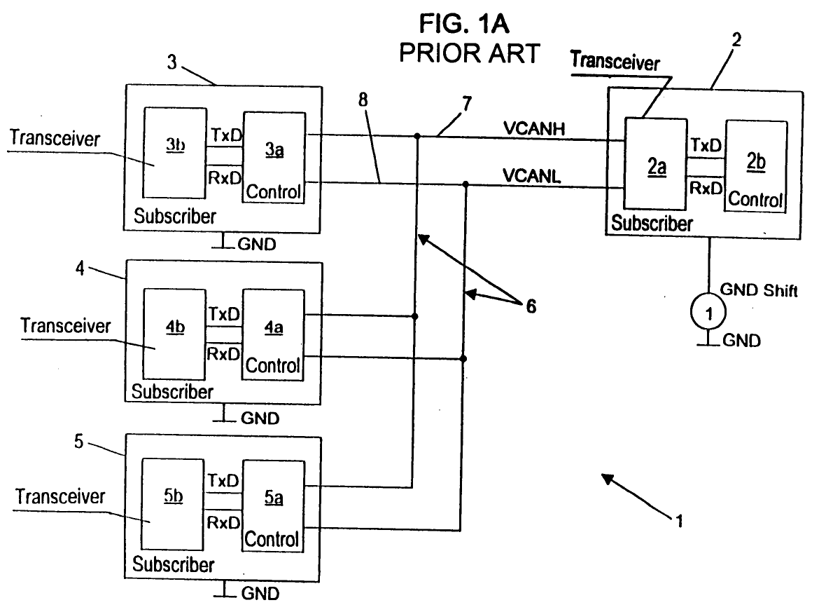

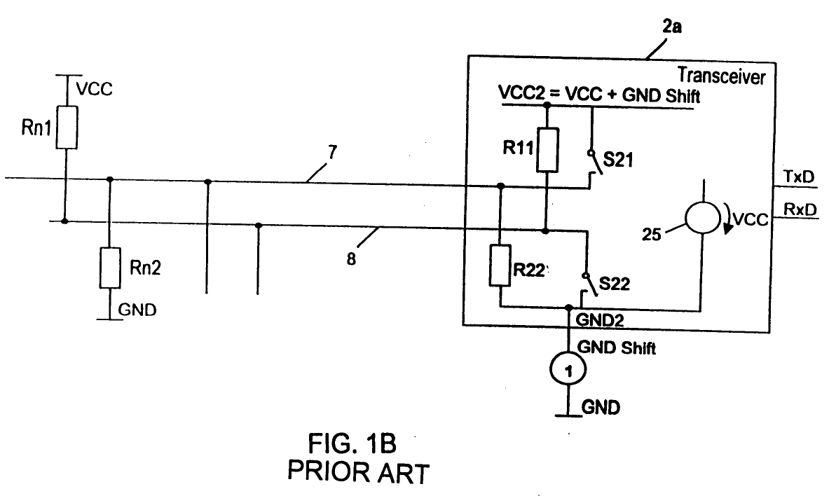

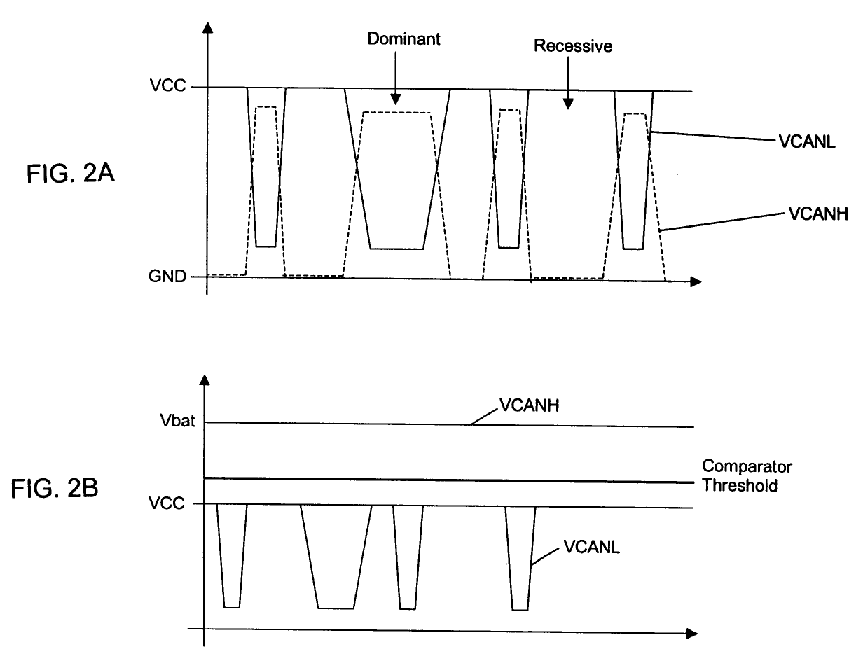

When a ground shift such as this has very high values, this can lead to an adverse effect up to and including interference with the data transmission. This will be explained briefly in the following text using an example and with reference to FIGS. 1 and 2.

FIG. 1a shows, schematically, a CAN bus system with two or more subscribers 2-4, which are connected to a common data bus 6 that is in the form of a two-wire bus and has a first line 7, the CANH line in the example, and a second line 8, the CANL line in the example. In FIG. 1a, VCANH denotes the potential on the CANH line 7, and VCANL denotes the potential on the CANL line 8.

Each of the subscribers 2-4 has a transmitting and receiving device 2a-4a (transceiver), which are each connected to a respective control unit 2b-4b. The individual transceivers 2a-4a are switched to a transmitting state or a receiving state via control signals TxD, RxD from the associated control unit 2b-4b.

In order to assist understanding of the potentials that occur on the bus lines 7, 8 during data transmission, FIG. 1b uses one of the transceivers 2a to illustrate, schematically, the internal configuration of the transceivers with the circuit components that are necessary for data transmission. The transceiver 2a has a voltage regulator 25, which produces a voltage VCC with respect to an internal reference ground potential GND2 in the transceiver 2a, in order to make a high potential VCC2 available in the transceiver. The reference ground potential GND2 in the transceiver 2a corresponds to the reference ground potential GND in the overall arrangement when no ground shift is present, and, in the case of a ground shift, is shifted through a value GND_{shift} with respect to the reference ground potential GND or ground. When there is no ground shift in the transceiver, the high potential VCC2 then corresponds to the potential VCC and, when a ground shift is present, it corresponds to the value VCC+GND_{shift}. A low potential which is available in the transceiver corresponds to the internal reference ground potential GND2.

The transceiver has terminating resistances R21, R22 in order to terminate the bus lines 7, 8, with the CANL line 8 being connected via a first resistor R21 to the internal reference ground potential GND2, or the internal low potential, and the CANH line being connected via a second terminating resistor R22 to the internal high potential VCC2. The reference symbol Rn1 in FIG. 1b denotes the first terminating resistance, and Rn2 denotes the second terminating resistance of any given other transceivers 3a-5a in the bus system. In the ideal operating situation, when there is no ground shift, and on the assumption that the terminating resistances R in all the transceivers 2a-5a are the same, the CANL line 8 is connected via a total terminating resistance R/n (where n is the number of transceivers 2a-5a) to a high potential VCC, and the CANH line 7 is connected via a total terminating resistance R/n (where n is the number of transceivers 2a-5a) to a low potential. This high potential results from the internal high potentials of the individual bus subscribers to which the CANL line 8 is connected via the first terminating resistances R21, Rn1. When none of the bus subscribers has any ground shift and if the supply voltages Vcc which are provided in all the bus subscribers are the same, this high potential corresponds to this voltage Vcc. If there is a ground shift in one or more of the bus subscribers, the high potential, to which the CANL line is connected via the terminating resistances, is governed by the internal high potentials of the individual bus subscribers. The low potential, to which the CANH line 7 is connected via the second terminating resistances R22, Rn2, corresponds to the ground potential GND when there is no ground shift in the system. When a ground shift is present in one or more bus subscribers, this low potential is governed by the internal low potentials of the individual bus subscribers.

In order to make it possible to transmit data via the bus, each transceiver 2a-5a has a first and a second switch S21, S22, which are illustrated only for the transceiver 2a in FIG. 1b. A first switch S21 is used to connect the CANH line 7 (which is terminated to the low potential via R22) to the internal high potential VCC2, and a second switch S22 is used to connect the CANL line 8 (which is terminated to a high potential via R21) to the internal low potential GND2.

FIG. 2a shows the profile of the two potentials VCANH, VCANL on the CANH line 7 and on the CANL line 8 for ideal, interference-free operation, when no ground shift is present, that is to say when VCC2=VCC and GND2=GND, with VCC denoting the voltage VCC which is available in all of the transceivers 2a-5a, and with GND denoting the low potential which is available in all of the transceivers 2a-5a.

If all of the transceivers 2a-5a are in a so-called recessive state, the potential on the bus lines 7, 8 is governed by the terminating resistances R21, R22, Rn1, Rn2, as a result of which the CANL line 8 is at the high potential VCC, and the CANL line is at the low potential. A transceiver, for example the transceiver 2a, is in a dominant state when both of its switches S21, S22 are closed. This then results in a higher potential on the CANL line 8 than on the CANH line 7, with the potential on the CANL line 8 being lower than the high potential VCC, owing to the voltage drop across the terminating resistances Rn2 of the other transceivers. In a corresponding manner, the potential on the CANH line 7 is higher than the low potential, owing to the voltage drop across the terminating resistances Rn1 of the other transceivers.

Data is transmitted from one transceiver to other transceivers in the system by keeping the receiving transceivers in the recessive state, while the transmitting transceiver, for example the transceiver 2a, changes between the dominant state and the recessive state, depending on the data to be transmitted.

The high potential VCC is produced in a manner which is not described in any more detail from a supply voltage Vbat by means of the voltage regulator 24 which is illustrated in FIG. 1b, being produced, for example, by the vehicle battery for a bus system which is used in a motor vehicle.

FIG. 2b shows a fault situation in a system in which there is no ground shift, in which situation the CANL line has a short circuit to this supply voltage Vbat, with this voltage being greater than the high potential VCC. In order to detect a short circuit such as this from one of the bus lines 7, 8 to the supply potential Vbat, it is known for the potentials on the bus lines 7, 8 in at least one of the transceivers to be compared by means of a comparator, which is not illustrated in any more detail, with a threshold voltage which is higher than the high potential VCC, and for a fault to be output if the potential on one of the bus lines 7, 8 exceeds this comparator threshold.

This procedure for fault detection may, however, incorrectly lead to detection of a fault when a ground shift is present in the system, as will be explained briefly in the following text. Let us assume that the bus subscriber 2 is transmitting data and that there is a ground shift, as a result of which the high potential VCC2 and the low potential of this subscriber are shifted through GND_{shift} with respect to the high potential VCC and the low potential of the other subscribers 3-5 when there is no ground shift. When the subscriber 2 is in the dominant mode, the potential VCANH on the CANH line 7 is then: VCANH=VCC+GND_{shift}. If the ground shift GND_{shift} is very high, it is now possible for the potential VCANH produced by the subscriber 2 to be higher than a comparator threshold (which is predetermined internally in the other bus subscribers 3-5) for identification of a short circuit between the CANH line 7 and the supply potential Vbat. In consequence, the bus subscribers 3-5 will identify a fault, even though no such short circuit is present.

A further disadvantage is that the fault is identified as a short circuit even though this is actually a ground shift problem. The ground shift problem is thus not identified at all. This could be overcome only by complex additional software.

In already known bus systems with fault identification devices as in the case of the already cited DE 195 23 031 A1, it has until now been possible to solve this problem only to the extent that the respective internal comparator threshold is set such that it allows a maximum ground shift of a few volts (for example GND_{shift}<2 volts), although this precludes applications with higher ground shift levels.

WO 97/36184 describes a method for testing ground contacts. In this case, each bus subscriber has two associated resistances. If the data bus is recessive, then an average level is produced on the data bus in the event of a ground shift. Although the method that is described in WO 97/36184 does not allow direct measurement of the ground shift, it is, however, possible to deduce that a ground shift is present.

WO 97/36399 describes a method for detection of a ground shift or of a poor ground contact. In this fault identification method, the data level to be transmitted during data transmission is compared with a predetermined, defined comparator threshold. Thus, if this comparator threshold is exceeded, there must either be a ground shift fault or an actual fault. In order to distinguish between these faults, the voltage is measured in the immediate vicinity of the bus network, for example via a resistance arrangement, and is compared with a predetermined voltage. The result of this comparison can be used to deduce whether a ground shift fault or some other fault is present.

Independently of this, both the fault identification in WO 97/36399 and that in WO 97/36184 are dependent on the presence of a ground shift.

Against this background, the present invention is based on the object of providing a further-developed method for fault identification in networked bus systems, as well as a bus system which carries out such a method.

According to the invention, this object is achieved by a method having the features of patent claim 1 and by a bus system having the features of patent claim 5.

The invention relates to a method for checking for line faults in a bus system which has at least two bus subscribers which are connected for the purpose of data communication with one another to a data bus which has at least two bus lines, with the bus subscribers being able to assume a recessive state and a dominant state, and with an internal high potential and an internal low potential being available in the bus subscribers. The method provides for the check for a line fault to be carried out in each case by the bus subscriber which is in the dominant state, and for the check for line faults to be carried out by comparison of voltage levels on the bus lines with threshold values which are related to the internal high level or to the internal low level of the bus subscriber.

This evaluation of the voltage levels on the bus lines using threshold values which are related to the internal potentials, in particular the internal low potential, means that a ground shift in the dominant bus subscriber carrying out the check cannot lead to an incorrectly identified fault.

In the bus system according to the invention for serial data transfer of binary data between at least two bus subscribers which are connected to a data bus, which contains at least two bus lines, for the purpose of data communication with one another, at least one of the bus subscribers has at least one control unit, at least one transceiver for transmitting and/or receiving data signals, and at least one device for fault identification, which has at least one fault detection means for comparison of at least one voltage level on one of the bus lines with a threshold value which is related to an internal low level or to an internal high level at the bus subscriber, with the at least one fault detection means providing a fault signal.

The bus system preferably has a first fault detection means for comparison of the voltage level on one of the data lines with a first threshold value and for provision of a first fault signal, as well as a second fault detection means for comparison of the voltage level on the other of the data lines with a second threshold value and for provision of a second fault signal.

One embodiment provides for the bus system to have a first data detection means for detection of transmitted data, for comparison of the voltage levels on the bus lines, with the first data detection means providing a first data signal. For detection of transmitted data, the bus system in this case preferably has at least one second data detection means, which compares the voltage level on at least one of the data lines with at least one threshold value which is related to the internal low level, in order to provide at least one second data signal, and has switching means for switching between the first data signal and the at least one second data signal as a function of the at least one fault signal.

The present invention is based on the knowledge that the identification of a bus fault need not necessarily be identified by all the bus subscribers in the bus system. In fact, it is sufficient for the identification and the signaling of a fault to be carried out by a single bus subscriber. This then carries out the appropriate measures for rectification, bypassing or overcoming (fault management routine) the fault, so that all the other bus subscribers are also included.

Since, in the case of the method according to the invention and the bus system according to the invention, the ground shift potential now no longer has any influence whatsoever on the fault identification, there is also no longer any need to take any additional measures to detect, suppress or prevent it. This significantly reduces the circuitry complexity of the individual bus subscribers and hence also the costs associated with them, without adversely affecting the performance of the bus system. In fact, the bus system according to the invention even results in the performance improving since, in the event of faults which are caused by a ground shift being signaled incorrectly, there is no longer any need to carry out time-consuming switching to an internal comparator. The effectiveness for the data transmission is advantageously also considerably improved, since the individual bus subscribers now rarely transmit incorrect fault messages (error frames). In consequence, the performance of the data transmission is even better than with known bus systems.

A further advantage is that a fault can now be unambiguously identified as a bus fault or as a ground shift fault. This at the same time minimizes the effort required for fault rectification and fault bypassing.

When designing the individual bus subscribers and the bus system, there is now no longer any need to ensure that a specific maximum ground shift, as is required according to the prior art, is never exceeded. This results in an additional degree of freedom for the definition and development of new bus systems.

In particular, the individual resistances, conductor paths and comparators of a bus subscriber can also each be optimally matched to the given conditions in this case.

The reference ground potential for all the bus subscribers is typically the potential of the reference ground. However, the invention is not restricted to systems and circuits such as these, which operate with respect to the reference ground. In fact, the bus subscribers and the bus system can also operate with respect to a different reference potential, for example the supply potential, that is to say the battery potential in motor vehicles.

The invention can also be applied to all bus systems in which comparisons are carried out between a bus level and an internal threshold, for example when a bus subscriber is in a state in which its reference potential for the production of the threshold is identical to the reference potential of the bus.

The invention can be applied particularly advantageously to bus systems used in motor vehicle electronics, for example to a CAN bus system. In this case, the invention can be used not only for a so-called high-speed CAN transceiver but also for a low-speed CAN transceiver. Furthermore, the invention is not exclusively restricted to CAN bus systems, but can be extended to differential bus systems with any desired configuration.

Advantageous refinements and developments of the invention can be found in the dependent claims and in the description with reference to the figures.

The invention will be explained in more detail in the following text using the exemplary embodiments which are indicated in the figures, in which:

FIG. 1 shows a block diagram of a two-wire bus system with four bus subscribers (FIG. 1a) and those components of a bus subscriber which are required for data transmission (FIG. 1b);

FIG. 2 shows the profile of the signal levels on a CANH line and on a CANL line of a bus system corresponding to FIG. 1a in the normal operating state (without faults) (FIG. 2a) and when a fault is present (FIG. 2b);

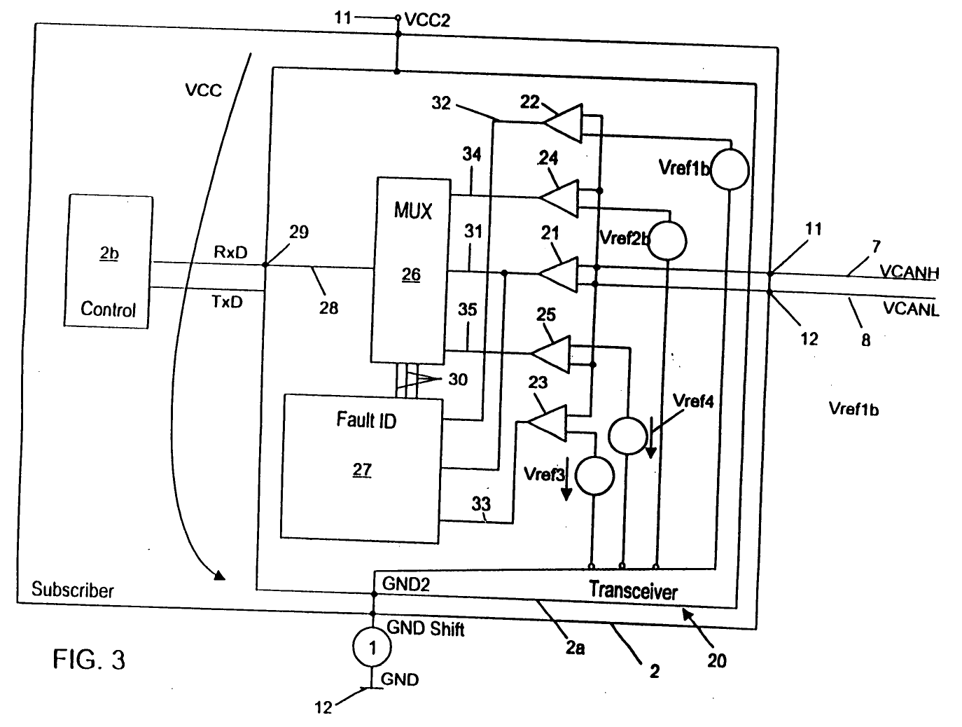

FIG. 3 shows a block diagram of a bus subscriber; and

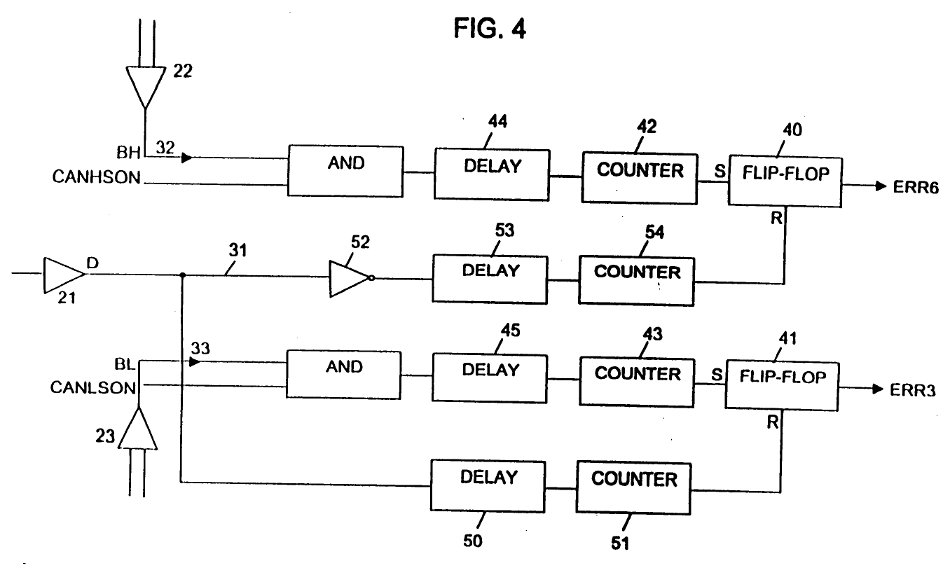

FIG. 4 shows a detailed block diagram of the fault identification device shown in FIG. 3.

Identical and functionally identical elements are provided with the same reference symbols in the figures, unless stated to the contrary.

In order to describe the method according to the invention, the bus system in which the method according to the invention is used will be described in more detail first of all. This bus system may, for example, have the configuration illustrated in FIG. 1, although other refinements of the bus system are also feasible.

In the block diagram shown in FIG. 1, the reference symbol 1 denotes the bus system according to the invention. The following text is based on the assumption that the networked bus system is a CAN bus system, in particular a so-called low-speed CAN bus system, although the invention is not restricted to this.

In the manner which has already been explained, the bus system in FIG. 1 has four bus subscribers 2-5, which are also referred to as modules or communication stations. For serial transmission of binary data by means of duplex signals, these bus subscribers 2-5 are coupled to a differential two-wire, typically twisted, data bus 6, with the data communication between the bus subscribers 2-5 which are connected to the bus 6 taking place in a known manner, which has already been explained in the introduction. The reference symbol 7 denotes the CANH line, and the reference symbol 8 denotes the CANL line of the data bus 6.

The physical coupling to the two-wire bus 6 is carried out via the transmitting and receiving device 2a-5a, the so-called transceiver, which is contained in each bus subscriber 2-5 and is designed for transmitting and/or receiving data via the data bus. For data transmission, the transmitting and receiving devices 2a-5a convert the data to be transmitted in the explained manner, with this data being provided by the respective control unit 2b-5b, from a logic level within the relevant bus subscriber 2-5 to two complementary transmission signals, whose waveform for normal interference-free operation is illustrated in FIG. 2a. For data reception, these transmission levels are converted by the transceivers 2a-5a to logic signals, which are processed further by the control units.

Bus transceivers 2a-5a are generally known in a large number of different embodiments, so that their various configurations will not be explained in any more detail in the following text.

The control units 2b-5b are, for example, programmable units which, for example, each contain a microprocessor, a microcontroller, a logic circuit or the like. Protocol functions are provided in the control units 2b-5b for data communication and are advantageously already monolithically integrated in microcontrollers which are specialized for applications such as these. One transceiver 2a-5a and a respective control unit 2b-5b are in each case electrically connected to one another via data lines.

The individual bus subscribers have an internal high potential and an internal low potential in order to ensure the data transmission as explained initially. As already explained, it is possible for the individual bus subscribers 2-5 to have an offset in their reference ground potential, the so-called ground shift. Only the bus subscriber 2 has such a ground shift in FIG. 1. This ground shift potential GND_{shift} ensures that the internal low potential GND2 of this subscriber is higher than the reference ground potential GND by the value GND_{shift}. Although only the bus subscriber 2 has a ground shift in FIG. 1, this effect may, of course, also occur in the other bus subscribers 3-5, and possibly to a different extent. The design of such a bus subscriber 2 with ground shift in general and of the corresponding transceiver 2a in particular will be described in more detail in the following text with reference to FIG. 3.

The internal high potential VCC2 can be applied to the CANH line 7, and the internal low potential GND2 can be applied to the CANL line 8 via the switching devices S21, S22 which are illustrated in FIG. 1b for the subscriber 2 and which, correspondingly, are also provided in one or more of the other bus subscribers 3-5. If there is no ground shift in the system, the internal high potential in all of the subscribers 2-5 corresponds to the value VCC, and the internal low potential in all of the subscribers 2-5 corresponds to the reference ground potential GND, with VCC denoting a voltage which is provided by an internal voltage regulator.

When the switches S21, S22 are open, the CANH line 7 is thus at a low logic level, and the CANL line 8 is at a high level. At the same time, this corresponds to one logic value of the binary data signals to be transmitted. If the respective other logic value is intended to be transmitted, a high level is applied to the CANH line 7, and a low level is applied to the CANL line 8, by closing the switches S21, S22. This allows data to be transmitted from each bus subscriber 2-5 via the lines 7, 8. The state or the respective level on the lines 7, 8 is referred to as being recessive when the switches are open, and as being dominant when the switches are closed.

During “rest operation” (the recessive state) of the data bus 6, for example when it is switched off, in the standby mode or in the power down mode, its state is defined by the termination illustrated in FIG. 1b which, apart from the resistances R21, R22 (passive termination) as illustrated in FIG. 1b, may also be formed by transistors (active termination). The operating state or the active state (dominant state) of the data bus 6 is reached by switching the output stage of any desired transceiver 2a-5a that is connected to the data bus 6 to be active. In the illustrated example, this is done by means of the control signal TxD=LOW, which is supplied from the respective control unit 2b to the transceiver 2a that is associated with it.

FIG. 3 shows a block diagram of the configuration of a bus subscriber which has a ground shift.

The bus subscriber 2 has data inputs/outputs 11, 12, via which it is connected to the two bus lines 7, 8. In the receiving mode, the transceiver 2a is supplied via the data inputs 11, 12 with data signals in the form of the voltage levels VCANH, VCANL of the bus lines 7, 8. In the transmitting mode, the transceiver 2a can transmit data via the lines 7, 8 to at least one other bus subscriber 3-5.

The bus subscriber 2 which is illustrated in FIG. 1 also has an evaluation circuit 20, whose input side is connected to the lines 7, 8. The evaluation circuit 20 is in this case a component of the transceiver 2a. The evaluation circuit 20 has first to fifth comparators 21-25 as data detection means or fault detection means, with the first, second and fourth comparators 21, 22 and 24 being connected on the input side to the CANH data line 7, and the first, third and fifth comparators 21, 23, 25 being connected to the CANL data line 8. The first comparator 21 in this case forms the differential input of the transceiver, and compares the signals VCANH, VCANL on the data lines 7, 8, while the second and fourth comparators 22, 24 compare the signal VCANH on the data line 7 with a first and second reference potential Vref1, Vref2, respectively, and the third and fifth comparators 23, 25 compare the signal VCANL on the data line 8 with a third and a fourth reference potential Vref3, Vref4, respectively. The first to fourth reference potentials Vref1-Vref4 are each related to a reference ground potential or low potential GND2 of the evaluation circuit, with this reference ground potential GND2 in the example having a ground shift GND_{shift} with respect to the ground potential GND.

The evaluation circuit 20 also has a multiplexer circuit 26 as well as a circuit for fault identification 27. The output signals 31, 34, 35 from the first, fourth and fifth comparators 21, 24, 25 are fed into the input side of the multiplexer 26, with these signals representing the data signals in a manner which is still to be explained. The circuit for fault identification 27 is connected on the input side to the outputs of the first, second and third comparators 21, 22, 23, with the output signals 32, 33 from the second and third comparators 22, 23, representing fault signals, in a manner which is still to be explained. The multiplexer 26 is connected via the line 28 to the output 29 of the evaluation circuit 20, and thus of the transceiver 2a. The function of this multiplexer 26 and of the fault identification circuit 27 will be explained in more detail in the following text.

The first comparator 21, which is connected on the input side to the inputs 11, 12 and thus to the lines 7, 8, compares the levels VCANH, VCANL on the bus lines 7, 8. On the output side, the comparator 21 produces an output signal which is dependent on VDIFF=VCANH−VCANL. The output signal 31 from this comparator 21 assumes a high level when VCANH is greater than VCANL, and otherwise assumes a low level. When the transceiver 2a is transmitting, the output signal 31 from the comparator assumes a high level when the transceiver is in the dominant state, and assumes a low level when it is in the recessive state. The output signal 31 from the first comparator reproduces the data transmitted via the bus. If no line faults are identified on the bus lines 7, 8, the multiplexer 26 makes the output signal from the comparator 21 available to the control circuit 2b for further processing.

If a fault now occurs, in which the CANH line 7 is permanently at a supply potential Vbat, as is illustrated in FIG. 2b, then the output signal from the comparator 21 assumes a high level permanently, provided that, taking into account the ground shift, this potential Vbat is greater than VCC2=VCC+GND_{shift}. It is thus no longer possible to reconstruct the data transmitted via the bus from the output signal 31 from the first comparator 21.

In order in a fault situation such as this to allow detection of the data transmitted via the bus, using the signal waveform of the potential VCANL on the CANL line, the fifth comparator 25 compares the potential VCANL on the CANL line 8 with the fourth reference potential Vref4 which is related to the internal reference ground potential GND2. This potential Vref4 is in this case chosen such that it is between the potentials which the CANL line assumes when a subscriber is in the dominant state and recessive state, in order thus to identify those transitions in the potential VCANL from a low potential to a high potential, and vice versa, which contain the information. This fourth comparison potential Vref4 is preferably: Vref4=VCC/2.

In order to identify a short circuit such as this from the CANH line to the supply potential Vbat, the CANH line 7 leads to the second comparator 22, which compares the signal VCANH related to ground GND with a threshold value Vref1+GND_{shift}. On this basis, the comparator 22 produces a fault signal on the line 32 only when the signal level VCANH is above the threshold value Vref1+GND_{shift}, indicating a short circuit from the line 7 to a supply potential. The line 32 leads to the fault identification circuit 27 which, when there is a short circuit such as this from the CANH line 7 to the supply potential Vbat, ensures that the output signal from the fifth comparator 25 is produced at the output of the transceiver 2a, rather than the output signal from the comparator 21, and that this is supplied to the control circuit 2b.

If a fault now occurs in which the CANL line 8 is permanently at a supply potential Vbat, then the output signal 31 from the first comparator 21 permanently assumes a low level, as a result of which it is impossible to reconstruct the data on the basis of the output signal 31 from the first comparator. In order, in a fault situation such as this, to allow detection of the data transmitted via the bus, on the basis of the signal waveform of the potential VCANH on the CANH line, the fourth comparator 24 compares the potential VCANH on the CANH line 7 with the second potential Vref2 which is related to the internal reference ground potential GND2. This potential Vref2 is in this case chosen such that it is between the potentials which the CANH line assumes when a subscriber is in the dominant state and recessive state, in order in this way to identify the transitions in the potential VCANH, which contain the information, from a low potential to a high potential, and vice versa. For this second comparison potential Vref2 is preferably: Vref2=VCC/2. In order to identify a short circuit such as this from the CANL line 8 to a supply potential Vbat, the third comparator 23 compares the potential VCANL, which is related to ground GND, on the CANL line 8 with a threshold value Vref3+GND_{shift}. The comparator 23 in this case produces a high signal on the line 33 when the signal level VCANL on the CANL line 8 is above the predetermined threshold value. The output 33 of the third comparator 23 leads to the fault identification circuit 27 which, when there is a short circuit such as this from the CANL line 7 to the supply potential Vbat, ensures that the output signal from the fourth comparator 24 is produced, rather than the output signal from the first comparator 21, at the output of the transceiver 2a, and this is supplied to the control circuit 2b.

The fault identification circuit 27 is designed to carry out fault identification only when the subscriber 2 is in the dominant state, as will be explained in the following text.

In this state, the CANH line 7 is connected via a switching device (which is not illustrated in any more detail in FIG. 3) to a high potential which corresponds approximately to the potential VCC2. This potential VCC2 is produced in the manner that has been explained by means of a voltage regulator, which is not illustrated in any more detail but which produces a voltage VCC related to the internal low potential GND2, which is higher at GND_{shift} than the ground potential GND. The comparison voltage Vref1 from the first comparator is higher than the voltage VCC, so that the threshold Vref1+GND_{shift} of the CANL line 7 is never reached during defect-free operation. A fault is identified only when VCANH becomes greater than VCANH+GND_{shift}, for example as a result of a short circuit to a supply voltage which is greater than VCC2. The supposed detection of a short circuit on the CANH line 7 as a result of a ground shift is precluded.

A short circuit between the CANL line and a supply potential is likewise detected when the subscriber is in the dominant state. When the subscriber is in the defect-free state, the potential on the CANL line when the subscriber is in the dominant state falls to a lower potential value. The comparator 23 compares the potential on the CANL line 8 with a potential Vref3, which is preferably greater than the voltage VCC that is related to the internal reference ground potential GND2, by the regulator, which is not illustrated in any more detail. A short circuit between the CANL line and a supply potential which is greater than VCC2 is in this case identified when the potential of the CANL line is greater than Vref3+GND_{shift} in the dominant state.

FIG. 4 uses a block diagram to show one exemplary embodiment of the fault identification circuit 27, by means of which a short circuit between the CANH line 7 and a supply voltage and between the CANL line 8 and a supply voltage can be identified. To assist understanding, the illustration likewise shows the comparators 21, 22, 23 which produce the input signals for this device.

A fault signal ERR3 is produced at the output of the fault identification circuit that is dependent on an output signal from the comparator 22, and thus on any short circuit between the CANH line 7 and a supply potential, and a fault signal ERR6, which is dependent on an output signal of the comparator 23 and hence on any short circuit between the CANL line 8 and the supply potential is also produced at the output of the fault identification circuit. These fault signals can be used for switching the multiplexer 26.

These two faults ERR3, ERR6 are identified when the comparator thresholds (which are predetermined by the reference potentials Vref1, Vref3) of the comparators 22 and 23, respectively, are exceeded, and when an output stage of the transceiver 2a is switched on, that is to say when the transceiver 2a is in the dominant state. By way of example, FIG. 1b shows an output stage such as this of the transceiver, comprising two switches S21, S22. Signals CANHSON, CANLSON are available in the transceiver 2a, indicating that the output stage has been switched on, in which case, with reference to the simple exemplary embodiment shown in FIG. 1b, the signal CANHSON indicates that the switch S21 has been switched on and thus that the CANH line 7 is connected to the upper drive potential VCC2, while the signal CANLSON indicates that the switch S22 has been switched on, and thus that the CANL line 8 is connected to the lower drive potential GND2.

In order to carry out fault identification exclusively in the dominant mode, the output signal from the comparator 22 is AND-linked to the signal CANHSON in order to produce the fault signal ERR3, and the output signal from the comparator 23 is AND-linked to the signal CANLSON in order to produce the fault signal ERR6. The TxD signal from the transceiver can then not be used directly in the present case since a time-out function is typically implemented in this case, which switches off this output stage if the TxD signal is in the dominant state for more than two milliseconds.

The governing factor is that the signals CANHSON and CANLSON which indicate whether the respective output stage is switched on or switched off are AND-linked to the output signals from the comparators 22, 23, as a result of which a fault signal ERR3 or ERR6, respectively, is produced only when the respective output stage is in the dominant mode.

The fault signals ERR3, ERR6 are produced at the outputs of the flipflops 40, 41 whose set inputs in the example are supplied via a respective counter 42, 43 and a delay element 44, 45 with signals which are produced from the AND-linking of in each case one of the signals CANHSON or CANLSON, respectively, with in each case one of the output signals from the comparators 22, 23.

The delay elements 44, 50 which are optionally provided are used to improve the interference immunity such that short pulses in the comparator output signals 32, 33 are not passed on to the respective downstream counters 42, 43. Short pulses such as these, which are shorter than the duration of normal dominant states, are masked out by the delay elements 44, 45.

The counters 42, 43 are likewise optionally provided and ensure that the respective downstream flipflop 40, 41 is set only when a predetermined count is reached, that is to say when fault states are identified during a predetermined number of successive dominant states of the transceiver.

The flipflops are reset on the basis of the output signal 31 from the comparator 21, with the flipflop 41 being supplied with this output signal 31 via a delay element 50 and a counter 51, and the flipflop 40 being supplied with this output signal 31 via an inverter 52 as well as a delay element 53 and a counter 54.

The flipflop 41, which is set when a short circuit is detected between the CANL line 8 and a supply potential, is in this case reset when the output signal from the first comparator 21 assumes a high level, which indicates that VCANH is greater than VCANL, so that there can no longer be short circuits between the CANL line and the supply potential. The flipflop 41 is thus reset on identification of a dominant state on the data bus. The delay element 50, which is optionally provided and is connected upstream of the reset input of the flipflop 41 is used in a corresponding manner to the delay elements 44, 45 in order to improve the interference immunity. The counter 51, which is likewise optionally provided, ensures that the flipflop 41 is reset only when a predetermined number of level changes from low to high have taken place in the comparator 21.

The flipflop 40, which is set when a short circuit is detected between the CANH line 7 and a supply potential is in this case reset when the output signal from the first comparator 21 assumes a low level, which indicates that VCANL is greater than VCANH, so that there can no longer be any short circuits between the CANH line and the supply potential. The flipflop 40 is thus reset on identification of a recessive state on the data bus. The delay element 53 which is optionally provided and is connected upstream of the reset input of the flipflop 40 is used in a corresponding manner to the delay elements 44, 45 to improve the interference immunity. The counter 54, which is likewise optionally provided, ensures that the flipflop 40 is reset only when a predetermined number of level changes from high to low have taken place in the comparator 21.

The circuit which is illustrated in FIG. 4 thus produces fault signals for further processing only when the respective output stage is in the dominant mode. Furthermore, the evaluation circuit 20 is designed to detect line faults independently of the presence of any ground shift, and nevertheless to carry out data detection even when a line fault has been detected.

In principle, the same circuit as that in FIGS. 1, 3 and 4 can be used for a high-speed CAN bus system in order to identify the corresponding faults. However, in this case, the delay times must be appropriately matched to the higher speed of the bus system. In this case, however, the fault ERR3, that is to say a short circuit between the line 7 and the supply voltage VCC, is less informative, since data transmission is no longer possible at all in this situation owing to the high-speed bus configuration.

The present invention has been explained with reference to the above description, in order to explain as well as possible the principle of the invention and its practical application, but the method according to the invention can, of course, be implemented in suitably modified forms in many different embodiments.

List of Reference Symbols

1 Bus system

2-5 Bus subscriber

2a-5a Transceiver

2b-5b Controller, programmable unit, microcontroller, microprocessor

6 Differential data bus

7 Bus lines, CANH line

8 Bus lines, CANL line

9, 10 Connections for the supply voltage

11, 12 Data inputs/outputs

20 Evaluation circuit

21-25 Comparators

26 Multiplexer circuit

27 Circuit for fault identification

28 Line

29 Output

30-35 Lines

40, 41 RS flipflop

42, 43, 51 Counter

44, 45 Delay element

50, 53 Delay element

51, 54 Counter

VCC, VCC2 First (positive) supply potential

GND, GND2 Second supply potential, potential of the reference ground, reference potential

GND_{shift} Offset in the reference potential, ground shift

VCANH Signal

VCANL Signal

ERR6, ERR3 Fault

CANH_{SON} Signal

CANL_{SON} Signal

TxD, Signals

RxD Signals

1. A method for checking for line faults in a bus system (1) which has at least two bus subscribers (2-5) which are connected for the purpose of data communication with one another to a data bus (6) which has at least two bus lines (7, 8), with the bus subscribers (2-5) being able to assume a recessive state and a dominant state, and with an internal high potential (VCC, VCC2) and an internal low potential (GND, GND2) being available in the bus subscribers,
with the check for a line fault being carried out by the bus subscriber (2) which is in the dominant state, and
with the check for line faults being carried out by comparison of voltage levels (VCANH, VCANL) on the bus lines (7, 8) with threshold values (Vref1, Vref3) which are related to the internal high level (VCC2) or to the internal low level (GND2) of the bus subscriber (2).

2. The method as claimed in claim 1, in which a supply voltage (VCC) which is related to the internal reference ground potential is provided in the bus subscribers, with the threshold values (Vref1, Vref3) being greater than this supply voltage (VCC), and a fault being identified when one of the voltage levels (VCANH, VCANL) on the bus lines (7, 8) is greater than the respective threshold value (Vref1, Vref3).

3. The method as claimed in claim 2, in which a fault is identified when one of the voltage levels (VCANH, VCANL) on the bus lines (7, 8) is greater than the respective threshold value (Vref1, Vref3) during a predetermined number of successive dominant states of the bus subscriber which is carrying out the fault identification.

4. The method as claimed in one of claims 1 to 3, in which the voltage levels (VCANH, VCANL) on the data lines (7, 8) are compared with one another for detection of transmitted data, in which case, on detection of a fault on one of the lines (7; 8), detection of transmitted data is carried out by means of a comparison of the voltage level (VCANL; VCANH) on the other line (8; 7) with a threshold value (Vref4; Vref2) which is related to the internal high potential or the internal low potential.

5. A bus system (1) for serial data transfer of binary data between at least two bus subscribers (2-5) which are coupled for the purpose of data communication with one another to a data bus (6) which contains at least two bus lines (7, 8), with a bus subscriber (2-5) having:
at least one control unit (2b-5b),
at least one transceiver (2a-5a) for transmission and/or reception of data signals (CANL, CANH), and
at least one device for fault identification for carrying out one of the methods mentioned above.

6. The bus system as claimed in claim 5, which, for fault detection, has at least one fault detection means for comparison of at least one voltage level (VCANH; VCANL) on one of the bus lines (7, 8) with a threshold value (Vref1, Vref3) which is related to the internal low level (GND2) or to the internal high level (VCC2), and for provision of a fault signal (32, 35).

7. The bus system as claimed in claim 6, which has:
a first fault detection means (22) for comparison of the voltage level (VCANH) on one (7) of the data lines with a first threshold value (Vref1), and for provision of a first fault signal (32), and
a second fault detection means (23) for comparison of the voltage level (VCAN1) on the other (8) of the data lines with a second threshold value (Vref3), and for provision of a second fault signal (33).

8. The bus system as claimed in claim 6 or 7, which, for detection of transmitted data, has a first data detection means (21) for comparison of the voltage levels (VCANH, VCANL) on the bus lines (7, 8), with the first data detection means providing a first data signal (31).

9. The bus system as claimed in claim 8, which has the following further features:
for detection of transmitted data, at least one second data detection means (24, 25) which compares the voltage level (VCANH, VCANL) on at least one of the data lines (7, 8) with at least one threshold value (Vref2, Vref4) which is related to the internal low level (GND2), in order to provide at least one second data signal (34, 35), and
switching means (26) for switching between the one data signal (31) and the at least one second data signal (33, 34) as a function of the at least one fault signal (32, 33).

10. The bus system as claimed in one of claims 5 to 9, characterized
in that the data bus (6) is designed for serial transmission of binary data by means of duplex signals (CANL, CANH) and, for this purpose, is in the form of a differential, two-wire data bus (6) whose two bus lines (7, 8) are twisted with one another.

11. The bus system as claimed in one of claims 5 to 10, characterized
in that the bus system (1) is in the form of a CAN bus system.
